(19) United States
(12) Patent Application Publication
(10) Pub. No.: US 2025/0349588 A1
(43) Pub. Date: Nov. 13, 2025

(54) WAFER LOAD PORT

(71) Applicants: HSIN-JUNG PENG, Taoyuan City (TW); TSUNG-CHE YU, Taoyuan City (TW); SHENG CHUAN TECHNOLOGY CO., LTD., Taoyuan City (TW)

(72) Inventors: Hsin-Jung Peng, Taoyuan City (TW); TSUNG-CHE YU, Taoyuan City (TW)

(73) Assignees: HSIN-JUNG PENG, Taoyuan City (TW); TSUNG-CHE YU, Taoyuan City (TW); SHENG CHUAN TECHNOLOGY CO., LTD., Taoyuan City (TW)

(21) Appl. No.: 19/191,228

(22) Filed: Apr. 28, 2025

(30) Foreign Application Priority Data
May 8, 2024 (TW) 113116994

(51) Int. Cl. H01L 21/677

(52) U.S. Cl. CPC H01L 21/67778

(57) ABSTRACT

A wafer load port is configured to load a FOUP, and the wafer load port has a mounting base, a load station, an opening part, a board, and a switch assembly. The load station is mounted on the top surface and is configured to load the FOUP. The opening part is mounted on a lateral side surface of the mounting base. An opening is formed through the opening part, and the opening is adjacent to the load station. The board may close the opening of the opening part. The switch assembly is mounted on the board and has a first embedding unit and a second embedding unit. The first embedding unit and the second embedding unit are located at different horizontal locations, and the first embedding unit and the second embedding unit are movable between a connection position and a waiting position.

### BACKGROUND OF THE INVENTION

### 1. Field of the Invention

The present invention relates to a wafer load port.

### 2. Description of the Prior Arts

In the semiconductor manufacturing process, wafers are processed at several workstations. However, to prevent contamination during waiting or transportation between workstations, the wafers are placed in a front opening unified pod (FOUP). A cover of the FOUP is opened and closed by a load port to ensure that the wafers are continuously kept in a dust-free state with the minimum airborne particles, such as the method of processing an object in a container and lid opening/closing system used in the method in Taiwan Invention No. I379374B.

The FOUPs have different sizes applicable to various wafer sizes. The size of the load port also needs to be changed for the FOUPs of different sizes. However, adding load ports will not only take up space in the wafer fab and complicate the wafer transportation line, but will also increase costs.

To overcome the shortcomings, the present invention provides a wafer load port to mitigate or obviate the aforementioned problems.

### SUMMARY OF THE INVENTION

The main objective of the present invention is to provide a wafer load port applicable for use with two FOUPs of different sizes. The wafer load port will mitigate the disadvantage that the FOUP needs to be used with the load port of another size, resulting in the need for multiple load ports and complicating the wafer transportation line.

The wafer load port is configured to load a FOUP, and the wafer load port has a mounting base, a load station, an opening part, a board, and a switch assembly.

The mounting base has a top surface. The load station is mounted on the top surface and is configured to load the FOUP. The load station is movable relative to the mounting base.

The opening part is mounted on a lateral side surface of the mounting base. An opening is formed through the opening part, and the opening is adjacent to the load station. The board may close the opening of the opening part.

The switch assembly is mounted on the board and has a first embedding unit and a second embedding unit. The first embedding unit and the second embedding unit are located at different horizontal locations, and the first embedding unit and the second embedding unit are movable between a connection position and a waiting position.

The advantage of the present invention is that the first embedding unit and the second embedding unit of the switch assembly can selectively connect to the FOUP, so that the wafer load port can be used with the FOUPs of two different sizes, which can save the cost of adding an additional load port and simplify the wafer transportation line. In addition, the slide cover is added to the wafer load port, so that the first embedding unit can be isolated from the outside to prevent contamination of the switch assembly when switching to the second embedding unit.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a wafer load port in accordance with the present invention;

FIG. 2 is an exploded view of the wafer load port in FIG. 1;

FIG. 3 is an exploded view of a switch assembly of the wafer load port in FIG. 1;

FIG. 4 is an exploded view of the switch assembly of the wafer load port in FIG. 1;

FIG. 5 is a cross-sectional view of the switch assembly of the wafer load port in FIG. 1;

FIG. 6 is a partial cross-sectional view of the wafer load port in FIG. 1 when a first embedding unit is located at a connection position;

FIG. 7 is a partial perspective view of the wafer load port in FIG. 1 when the first embedding unit is located at the connection position;

FIG. 8 is a partial cross-sectional view of the wafer load port in FIG. 1 when a second embedding unit is located at the connection position; and

FIG. 9 is a partial perspective view of the wafer load port in FIG. 1 when the second embedding unit is located at the connection position.

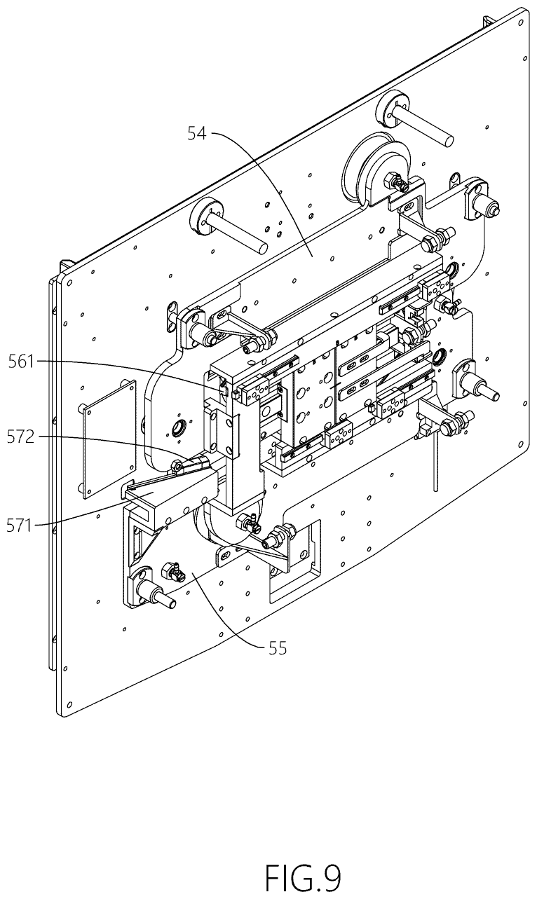

### DETAILED DESCRIPTION OF THE PREFERRED EMBODIMENTS

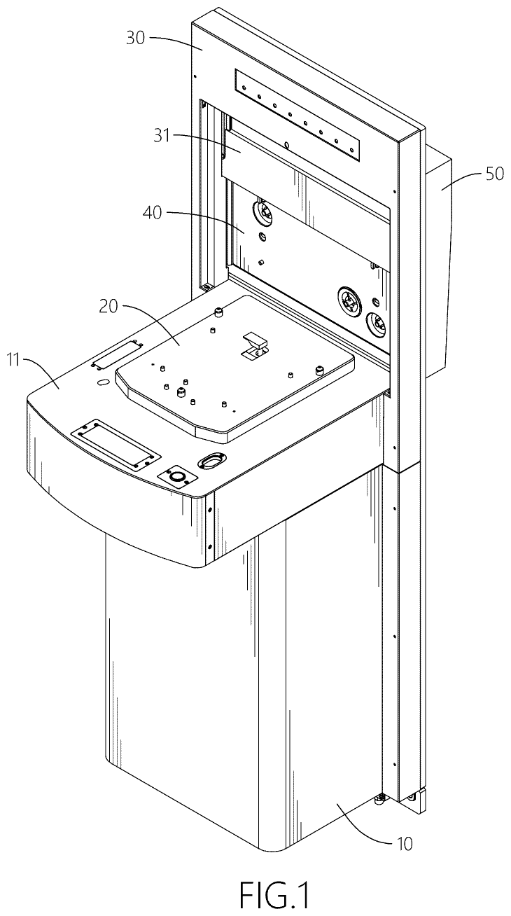

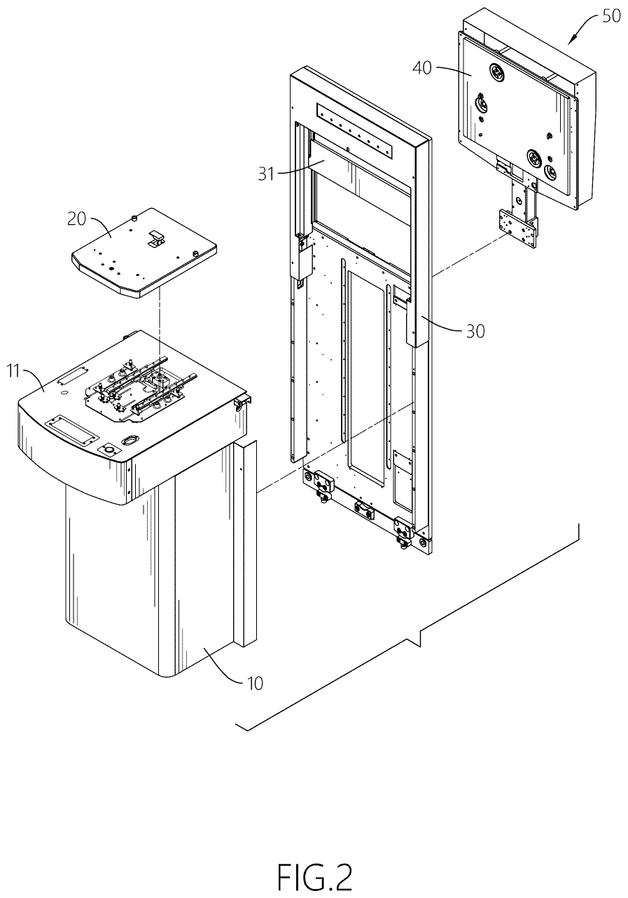

With reference to FIG. 1 and FIG. 2, a wafer load port in accordance with the present invention is configured to load a FOUP. The wafer load port comprises a mounting base 10, a load station 20, an opening part 30, a board 40, and a switch assembly 50.

The mounting base 10 comprises a top surface 11. The load station 20 is mounted on the top surface 11 of the mounting base 10 and is configured to load the FOUP. The load station 20 is movable relative to the mounting base 10. The opening part 30 is mounted on a lateral side surface of the mounting base 10, and an opening is formed through the opening part 30. The opening is adjacent to the load station 20. Meanwhile, the FOUP is adjacent to the opening. The opening part 30 comprises a slide cover 31 selectively covering part of the opening. The board 40 can close the opening of the opening part 30.

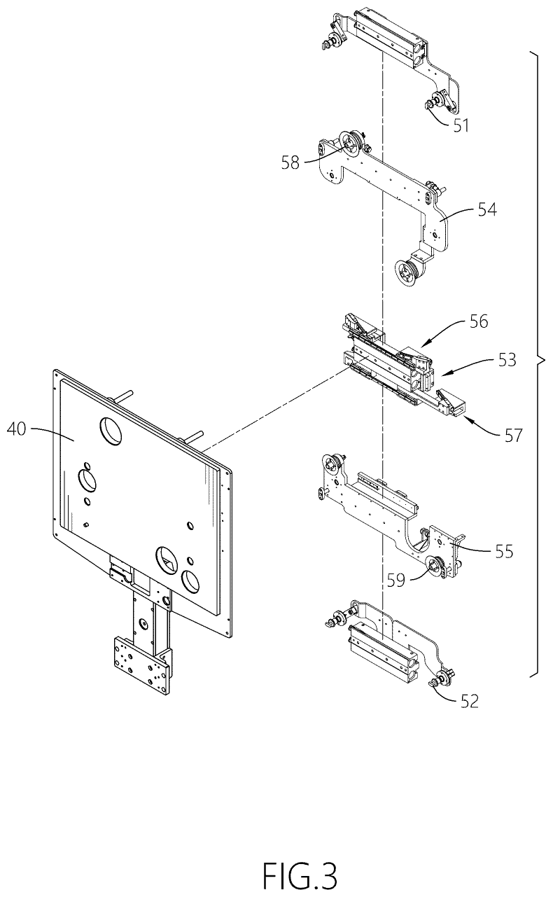

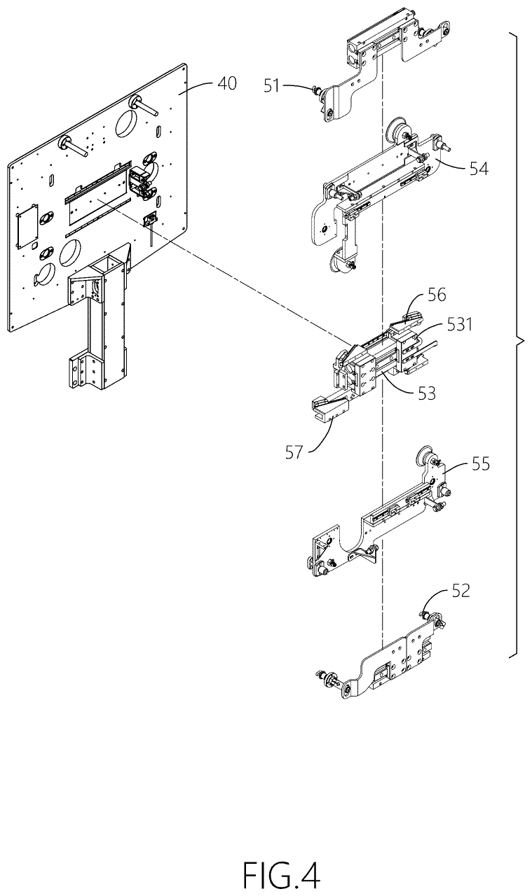

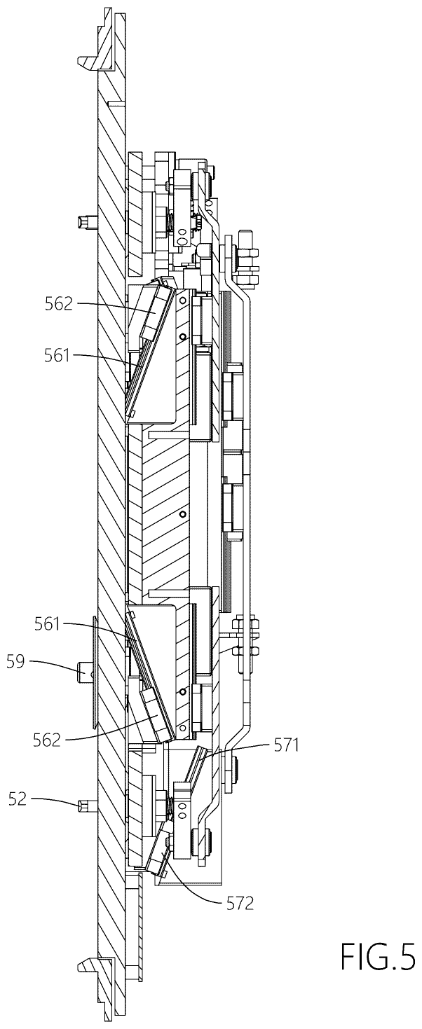

Refer to FIG. 3 to FIG. 5. The switch assembly 50 is mounted on the board 40 and comprises a first embedding unit 51, a second embedding unit 52, a drive unit 53, a first connecting part 54, a second connecting part 55, a first slide rail unit 56, a second slide rail unit 57, a first gas nozzle unit 58, and a second gas nozzle unit 59.

The first embedding unit 51 and the second embedding unit 52 move between a connection position and a waiting position. The connection position and the waiting position are located at two imaginary vertical planes parallel with the board 40, and the waiting position is farther away from the board 40 than the connection position. In this embodiment, the first embedding unit 51 or the second embedding unit 52 moves through the board 40 and connects to the FOUP when the first embedding unit 51 or the second embedding unit 52 is at the connection position. The first embedding unit 51 or the second embedding unit 52 moves to a side of the board 40 opposite to the FOUP when the first embedding unit 51 or the second embedding unit 52 is at the waiting position.

The first embedding unit 51 and the second embedding unit 52 are respectively located at the connection position and the waiting position. In other words, the second embedding unit 52 is located at the waiting position when the first embedding unit 51 is located at the connection position, and the second embedding unit 52 is located at the connection position when the first embedding unit 51 is located at the waiting position.

The first embedding unit 51 and the second embedding unit 52 are located at different horizontal locations, so that the first embedding unit 51 and the second embedding unit 52 can connect to the FOUPs of different sizes. In this embodiment, the first embedding unit 51 is higher than the second embedding unit 52 in horizontal location, so that the first embedding unit 51 may connect to the larger FOUP, the second embedding unit 52 may connect to the smaller FOUP. When the second embedding unit 52 connects to the smaller FOUP, the slide cover 31 of the opening part 30 may be lowered to contact the smaller FOUP, so that dust will not enter the switch assembly 50 through the first embedding unit 51.

The drive unit 53 is configured to drive the first embedding unit 51 and the second embedding unit 52 to move, and the drive unit 53 comprises a moving part 531. In this embodiment, the first connecting part 54 connects to the drive unit 53 and the first embedding unit 51, and the drive unit 53 drives the first connecting part 54 and the first embedding unit 51 to move between the connection position and the waiting position. The second connecting part 55 connects to the drive unit 53 and the second embedding unit 52, and the drive unit 53 drives the second connecting part 55 and second embedding unit 52 to move between the connection position and the waiting position. In this embodiment, the first connecting part 54 and the second connecting part 55 are each a plate, but in another embodiment, the shape of the first connecting part 54 and the second connecting part 55 is not limited thereto. In this embodiment, the moving part 531 connects to the first slide rail unit 56 and the second slide rail unit 57, so that the moving part 531 may drive the first slide rail unit 56 and the second slide rail unit 57 to move when the moving part 531 is moving.

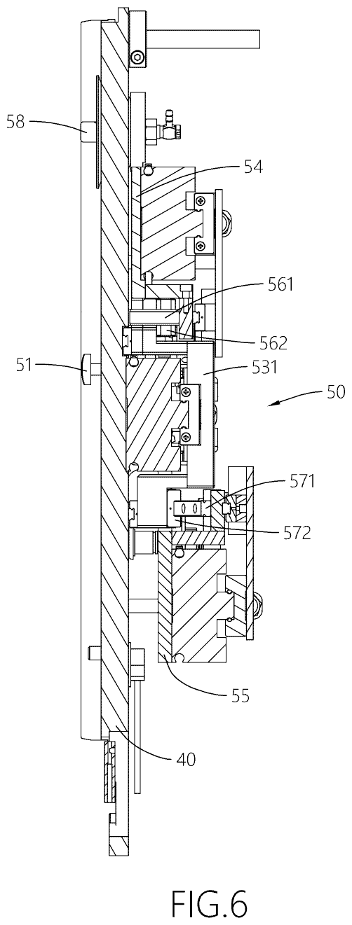

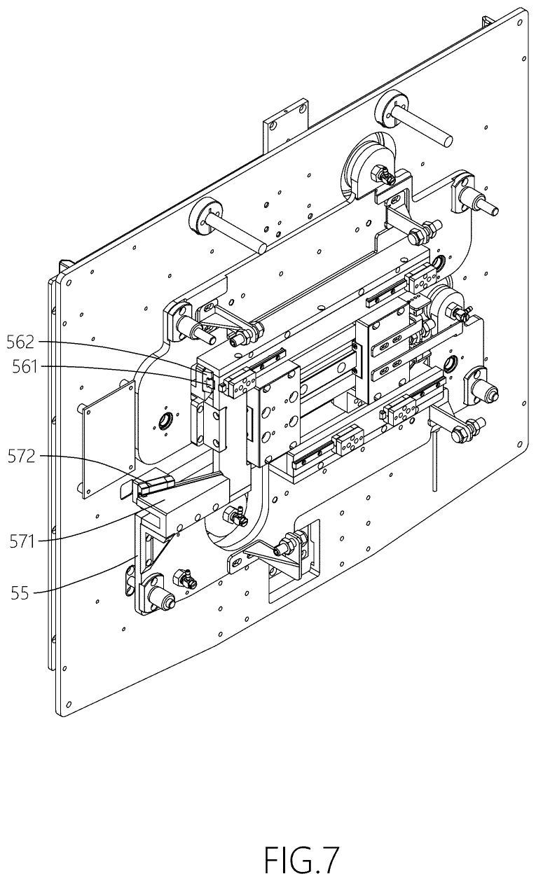

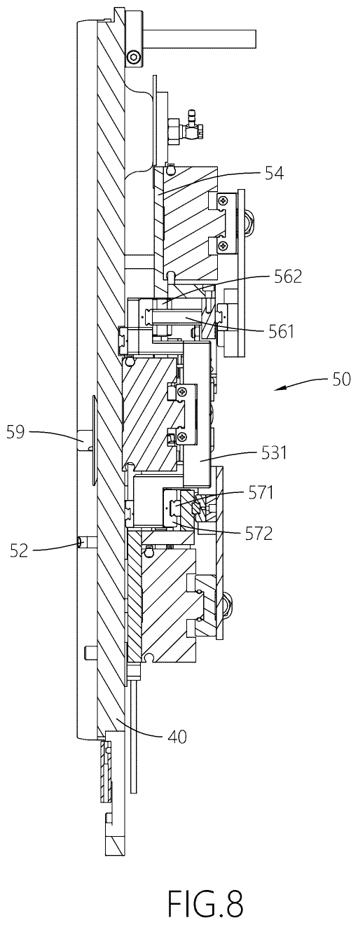

With reference to FIG. 6 to FIG. 8, the first slide rail unit 56 comprises at least one first slide part 561 and at least one second slide part 562. The at least one first slide part 561 is securely mounted on the first connecting part 54 and comprises a first incline. The first incline is inclined relative to a moving direction of the first embedding unit 51. The at least one second slide part 562 is securely mounted on the moving part 531 of the drive unit 53, so that the drive unit 53 may drive the at least one second slide part 562 to move, and the at least one second slide part 562 may push the at least one first slide part 561 and slide along the first incline of the at least one first slide part 561.

In this embodiment, the first slide rail unit 56 comprises two first slide parts 561 and two second slide parts 562. The two second slide parts 562 respectively slide along the first inclines of the two first slide parts 561, and the first inclines of the two first slide parts 561 are inclined in opposite directions. In this embodiment, the first inclines of the two first slide parts 561 are inclined toward the board 40. Since the first inclines of the two first slide parts 561 are inclined in opposite directions, the displacements parallel to the board 40 are offset, leaving only the displacement perpendicular to the board 40. Therefore, when the two second slide parts 562 slide on the two first inclines, the first connecting part 54 can be driven to move toward or away from the board 40.

In this embodiment, when the second slide part 562 is located at an end of the first incline away from the board 40, the second slide part 562 drives the first embedding unit 51 to the connection position. When the second slide part 562 is located at an end of the first incline close to the board 40, the second slide part 562 drives the first embedding unit 51 to the waiting position.

The second slide rail unit 57 comprises at least one third slide part 571 and at least one fourth slide part 572. The at least one third slide part 571 is securely mounted on the first connecting part 54 and comprises a second incline. The second incline is inclined relative to a moving direction of the second embedding unit 52. The at least one fourth slide part 572 is securely mounted on the moving part 531 of the drive unit 53, so that the drive unit 53 may drive the at least one fourth slide part 572 to move, and the at least one fourth slide part 572 may push the at least one third slide part 571 and slide along the second incline of the at least one third slide part 571.

In this embodiment, the second slide rail unit 57 comprises two third slide parts 571 and two fourth slide parts 572. The two fourth slide parts 572 respectively slide along the second inclines of the two third slide parts 571, and the second inclines of the two third slide parts 571 are inclined in opposite directions. In this embodiment, the second inclines of the two third slide parts 571 are inclined toward the board 40. Since the second inclines of the two third slide parts 571 are inclined in opposite directions, the displacements parallel to the board 40 are offset, leaving only the displacement perpendicular to the board 40. Therefore, when the two fourth slide parts 572 slide on the two second inclines, the second connecting part 55 can be driven to move toward or away from the board 40.

In this embodiment, when the fourth slide part 572 is located at an end of the second incline away from the board 40, the fourth slide part 572 drives the second embedding unit 52 to the connection position. When the fourth slide part 572 is located at an end of the second incline close to the board 40, the fourth slide part 572 drives the second embedding unit 52 to the waiting position.

The first gas nozzle unit 58 is securely mounted on the first connecting part 54 and is movable between the connection position and the waiting position as the first connecting part 54 is moving. The second gas nozzle unit 59 is securely mounted on the second connecting part 55 and is movable between the connection position and the waiting position as the second connecting part 55 is moving. In other words, when the first embedding unit 51 moves to the connection position, the first gas nozzle unit 58 also moves to the connection position. When the second embedding unit 52 moves to the connection position, the second gas nozzle unit 59 also moves to the connection position.

In this embodiment, when the first embedding unit 51 is located at the connection position, the first embedding unit 51 may connect to the FOUP. Meanwhile, the first connecting part 54, the first slide rail unit 56, and the first gas nozzle unit 58 are all located at the connection position, and the second embedding unit 52, the second connecting part 55, the second slide rail unit 57, and the second gas nozzle unit 59 are all located at the waiting position. To switch the first embedding unit 51 to the waiting position (the second embedding unit 52 moves to the connection position), the drive unit 53 drives the second slide parts 562 to move and pushes the first slide parts 561. Precisely, the second slide parts 562 slide on the first inclines of the first slide parts 561, and the second slide parts 562 slide to the end of the first inclines close to the board 40. Meanwhile, the second slide parts 562 push the first slide parts 561 away from the board 40 and drive the first connecting part 54, the first embedding unit 51 and the first gas nozzle unit 58 away from the board 40 to the waiting position. Similarly, the drive unit 53 drives the fourth slide parts 572 to move and pushes the third slide parts 571. Precisely, the fourth slide parts 572 slide on the second inclines of the third slide parts 571, and the fourth slide parts 572 slide to the end of the second inclines away from the board 40. Meanwhile, the fourth slide parts 572 push the third slide parts 571 toward the board 40 and drive the second connecting part 55, the second embedding unit 52, and the second gas nozzle unit 59 moves toward the board 40 to the connection position. Therefore, the second embedding unit 52 may connect to the FOUP, completing the switching of the FOUPs of different sizes.

The advantage of the present invention is that the first embedding unit 51 and the second embedding unit 52 of the switch assembly 50 can selectively connect to the FOUP, so that the wafer load port can be used with the FOUPs of two different sizes, which can save the cost of adding an additional load port and simplify the wafer transportation line. In addition, the slide cover 31 is added to the wafer load port, so that the first embedding unit 51 can be isolated from the outside to prevent contaminating the switch assembly 50 when switching to the second embedding unit 52.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A wafer load port configured to load a front opening unified pod (FOUP), and the wafer load port comprising:
a mounting base comprising a top surface;
a load station mounted on the top surface and configured to load the FOUP, the load station being movable relative to the mounting base;
an opening part mounted on a lateral side surface of the mounting base and an opening formed through the opening part, the opening being adjacent to the load station;
a board capable of closing the opening of the opening part;
a switch assembly mounted on the board and comprising:
a first embedding unit and a second embedding unit, the first embedding unit and the second embedding unit located at different horizontal locations, and the first embedding unit and the second embedding unit being movable between a connection position and a waiting position.

2. The wafer load port as claimed in claim 1, wherein the switch assembly comprises:
a drive unit;
a first connecting part connecting the drive unit and the first embedding unit, and the drive unit capable of driving the first connecting part and the first embedding unit to move between the connection position and the waiting position;
a second connecting part connecting the drive unit and the second embedding unit, and the drive unit capable of driving the second connecting part and the second embedding unit to move between the connection position and the waiting position.

3. The wafer load port as claimed in claim 2, wherein the switch assembly comprises:
a first slide rail unit comprising:
at least one first slide part securely mounted on the first connecting part and comprising a first incline;
at least one second slide part securely mounted on the drive unit and being capable of sliding along the first incline of the at least one first slide part;
a second slide rail unit comprising:
at least one third slide part securely mounted on the second connecting part and comprising a second incline;
at least one fourth slide part securely mounted on the drive unit and being capable of sliding along the second incline of the at least one third slide part.

4. The wafer load port as claimed in claim 3, wherein,
the first embedding unit moves to the connection position when the at least one second slide part is located at the first incline and away from the board; the first embedding unit moves to the waiting position when the at least one second slide part is located at the first incline and close to the board;
the second embedding unit moves to the connection position when the at least one fourth slide part is located at the second incline and away from the board; the second embedding unit moves to the waiting position when the at least one fourth slide part is located at the second incline and close to the board.

5. The wafer load port as claimed in claim 4, wherein,
the second embedding unit is located at the waiting position when the first embedding unit is located at the connection position; and
the second embedding unit is located at the connection position when the first embedding unit is located at the waiting position.

6. The wafer load port as claimed in claim 5, wherein,
the first incline and the second incline are inclined in opposite directions; and
the drive unit comprises a moving part, and the at least one second slide part and the at least one fourth slide part are securely mounted on the moving part.

7. The wafer load port as claimed in claim 3, wherein,
the first slide rail unit comprises two said first slide parts and two said second slide parts, the two second slide parts respectively slide along the first inclines of the two first slide parts, and the first inclines of the two first slide part are inclined in opposite directions; and
the second slide rail unit comprises two said third slide parts and two said fourth slide parts, the two fourth slide parts respectively slide along the second inclines of the two third slide parts, and the second inclines of the two third slide parts are inclined in opposite directions.

8. The wafer load port as claimed in claim 6, wherein,
the first slide rail unit comprises two said first slide parts and two said second slide parts, the two second slide parts respectively slide along the first inclines of the two first slide parts, and the first inclines of the two first slide part are inclined in opposite directions; and
the second slide rail unit comprises two said third slide parts and two said fourth slide parts, the two fourth slide parts respectively slide along the second inclines of the two third slide parts, and the second inclines of the two third slide parts are inclined in opposite directions.

9. The wafer load port as claimed in claim 2, wherein, the switch assembly comprises:
a first gas nozzle unit securely mounted on the first connecting part, and being movable between the connection position and the waiting position along with the first connecting part when the first connecting part is moving;
a second gas nozzle unit securely mounted on the second connecting part, and being movable between the connection position and the waiting position along with the second connecting part when the second connecting part is moving.

10. The wafer load port as claimed in claim 8, wherein, the switch assembly comprises:
a first gas nozzle unit securely mounted on the first connecting part, and being movable between the connection position and the waiting position along with the first connecting part when the first connecting part is moving;
a second gas nozzle unit securely mounted on the second connecting part, and being movable between the connection position and the waiting position along with the second connecting part when the second connecting part is moving.

11. The wafer load port as claimed in claim 1, wherein, the opening part further comprises:
a slide cover selectively covering a part of the opening.

12. The wafer load port as claimed in claim 10, wherein, the opening part further comprises:
a slide cover selectively covering a part of the opening.
